(19) United States
(12) Patent Application Publication
(10) Pub. No.: US 2016/0351416 A1
(43) Pub. Date: Dec. 1, 2016

(54) ELECTRODE STRUCTURE AND METHOD OF MANUFACTURING THE SAME, DISPLAY SUBSTRATE AND DISPLAY DEVICE

(71) Applicants: BOE TECHNOLOGY GROUP CO., LTD., Beijing (CN); BEIJING BOE OPTOELECTRONICS TECHNOLOGY CO., LTD., Beijing (CN)

(72) Inventors: Jiuxia Yang, Beijing (CN); Feng Bai, Beijing (CN)

(21) Appl. No.: 14/912,622

(22) PCT Filed: May 29, 2015
(86) PCT No.: PCT/CN2015/080263

§ 371 Date: Feb. 18, 2016

(30) Foreign Application Priority Data
Jan. 30, 2015 (CN) 201510051430.0

(51) Int. Cl. H01L 21/3205; H01L 21/321; H01L 21/3213; H01L 21/288; H01L 21/3215

(52) U.S. Cl. CPC H01L 21/32056; H01L 21/288; H01L 21/3215; H01L 21/32134; H01L 21/321

(57) ABSTRACT

The present invention discloses an electrode structure, a method of manufacturing an electrode structure, a display substrate and a display device. The method of manufacturing an electrode structure includes: forming a layer of carbon nanotube film on a substrate; performing a doping process in the layer of carbon nanotube film by using a modifier material, and performing a patterning process on the doped layer of carbon nanotube film so as to form a pattern including first electrode; or performing a patterning process on the layer of carbon nanotube film so as to form a patterns including carbon nanotube electrodes, and performing a doping process in the pattern of the carbon nanotube electrodes so as to form a pattern including first electrodes; as such, the carbon nanotubes material is doped with the modifier material, such that the formed first electrode has a lower square resistance value, which may meet the conductivity requirement of the flexible electrode of the flexible display.

### FIELD OF THE INVENTION

The present invention relates to field of display technology, and especially to an electrode structure and a method of manufacturing the same, a display substrate and a display device.

### DESCRIPTION OF THE RELATED ART

Currently, with the rapid development of flexible display technology, a flexible display device has become an important development direction of the field of display with its characteristics such as light and thin, durability, bendability and the like.

Electrodes of the flexible display device, such as pixel electrodes, are required to have good mechanical strength and flexibility, so as to meet the bendable characteristics of the flexible display device. Because mechanical strength and flexibility of a transparent conductive oxide material such as indium tin oxide (ITO), indium zinc oxide (IZO) or the like are weaker, the transparent conductive oxide is not suitable for making the electrodes of the flexible display device. Conventional flexible display devices generally use electrodes of carbon material. Although use of carbon material may meet the requirements of the mechanical strength and flexibility of the flexible display device, the electrode made of the carbon material has a larger square resistance value, which will increase power consumption of the flexibility display device.

Therefore, it is an urgent technical problem to be solved those skilled in the art that a flexible electrode is provided with a lower square resistance value so as to be applicable in the flexible display.

### SUMMARY OF THE INVENTION

Considering the above, embodiments of the present invention provide an electrode structure, a method of manufacturing the electrode structure, a display substrate and a display device, so that a flexible electrode having a lower square resistance value can be manufactured so as to be applicable in the flexible display.

Accordingly, embodiments of the present invention provide a method of manufacturing an electrode structure, comprises:

forming a layer of carbon nanotube film on a substrate;

performing a doping process in the layer of carbon nanotube film by using a modifier material, and

performing a patterning process on the layer of carbon nanotube film so as to form a pattern including first electrodes.

In an exemplary embodiment, after forming the pattern including the first electrodes, the method further comprises:

forming a layer of protective film by using a highly conductive material on the substrate formed with the pattern of the first electrodes, and

performing a patterning process on the layer of protective film so as to form a pattern of second electrodes each corresponding to one of the first electrodes, wherein the second electrode at least covers an upper surface of the corresponding one of the first electrodes.

In an exemplary embodiment of the above mentioned method according to the present invention, forming the layer of protective film by using the highly conductive material on the substrate formed the pattern of the first electrodes comprises:

coating and drying, on the substrate formed with the pattern of the first electrodes, one or more of 3,4-ethylene dioxythiophene/polystyrene sulfonate material, polyparaphenylene vinyl material, polythiophene based materials, polysilane based materials, triphenylmethane based materials, triarylamine-based materials and pyrazoline-based materials.

In an exemplary embodiment, the patterning process on the layer of carbon nanotube film is performed after performing the doping process in the layer of carbon nanotube film by using the modifier material. Alternatively, after performing the doping process in the layer of carbon nanotube film, and before performing the patterning process on the doped layer of carbon nanotube film, the above mentioned method according to embodiments of the present invention further comprises:

forming a layer of protective film on the doped layer of carbon nanotube film by using a highly conductive material; and

performing the doping process in the doped layer of carbon nanotube film comprises:

performing a patterning process on the layer of protective film and the doped layer of carbon nanotube film so as to form a pattern including the first electrodes and second electrodes, wherein each second electrode corresponds to one of the first electrodes, and the second electrode at least covers an upper surface of the corresponding one of the first electrodes.

In an exemplary embodiment of the above mentioned method according to the present invention, forming the layer of protective film on the doped layer of carbon nanotube film by using the highly conductive material comprises:

coating and drying, on the doped layer of carbon nanotube film, one or more of 3,4-ethylene dioxythiophene/polystyrene sulfonate material, polyparaphenylene vinyl material, polythiophene based materials, polysilane based materials, triphenylmethane based materials, triarylamine-based materials and pyrazoline-based materials.

In an exemplary embodiment, the patterning process on the layer of carbon nanotube film is performed before performing the doping process in the layer of carbon nanotube film by using the modifier material.

In an exemplary embodiment of the above mentioned method according to the present invention, foil ling the layer of carbon nanotube film on the substrate comprises:

coating carbon nanotube dispersion liquid on the substrate; and

performing a drying process on the coated carbon nanotube dispersion liquid.

In an exemplary embodiment of the above mentioned method according to the present invention, forming the layer of carbon nanotube film on the substrate comprises:

coating a solidifiable material on the substrate;

forming the layer of carbon nanotube film on the solidifiable material through a film-drawing process; and

performing a solidification treatment on the substrate formed with the layer of carbon nanotube film.

In an exemplary embodiment of the above mentioned method according to the present invention, when the patterning process on the layer of carbon nanotube film is performed after performing the doping process in the layer of carbon nanotube film by using the modifier material, performing the doping process in the layer of carbon nanotube film comprises:

placing the substrate formed with the layer of carbon nanotube film into a modifier solution for a preset time;

removing the substrate from the modifier solution, and cleaning the substrate by using deionized water; and

drying the cleaned substrate.

In an exemplary embodiment of the above mentioned method according to the present invention when the patterning process on the layer of carbon nanotube film is performed after performing the doping process in the layer of carbon nanotube film by using the modifier material, performing the doping process in the pattern of the carbon nanotube electrodes comprises:

placing the substrate formed with the pattern of the carbon nanotube electrodes into a modifier solution for a preset time;

removing the substrate from the modifier solution, and cleaning the substrate by using deionized water; and

drying the cleaned substrate.

In an exemplary embodiment, the modifier solution comprises one or more of nitrogen dioxide solution, bromine solution, nitric acid solution, thionyl chloride solution, perfluorinated sulfonic acid ester solution and tetrafluorotetracyanoquinodimethane subimed solution, and the preset time is 5 min to 30 min.

In an exemplary embodiment of the above mentioned method according to the present invention, when the patterning process on the layer of carbon nanotube film is performed after performing the doping process in the layer of carbon nanotube film by using the modifier material, performing the doping process in the layer of carbon nanotube film comprises:

spraying modifier solution on the substrate formed with the layer of carbon nanotube film within a preset time;

cleaning the substrate sprayed with modifier solution by using deionized water; and

drying the cleaned substrate.

In an exemplary embodiment of the above mentioned method according to the present invention, when the patterning process on the layer of carbon nanotube film is performed before performing the doping process in the layer of carbon nanotube film by using the modifier material, performing the doping process in the pattern of the carbon nanotube electrodes comprises:

spraying a modifier solution on the substrate formed with pattern of the carbon nanotube electrodes within a preset time;

cleaning the substrate sprayed with modifier solution by using deionized water; and

drying the cleaned substrate.

In an exemplary embodiment, the sprayed modifier solution comprises one or more of nitrogen dioxide solution, bromine solution, nitric acid solution, thionyl chloride solution, perfluorinated sulfonic acid ester solution and tetrafluorotetracyanoquinodimethane subimed solution, the preset time is 5 min to 30 min.

In an exemplary embodiment of the above mentioned method according to the present invention, when the patterning process on the layer of carbon nanotube film is performed after performing the doping process in the layer of carbon nanotube film by using the modifier material, performing the patterning process on the doped layer of carbon nanotube film comprises:

performing a laser burning process on the doped layer of carbon nanotube film;

performing a patterning process on the layer of carbon nanotube film, specifically comprising:

performing a laser burning process on the layer of carbon nanotube film.

Embodiments of the present invention further provide an electrode structure, which is manufactured by using the above mentioned method according to embodiments of the present invention.

Embodiments of the present invention further provide an electrode structure, comprising an electrode made of a carbon nanotube film doped with a modifier material, the carbon nanotube film doped with the modifier material having a lower square resistance value than that of a carbon nanotube film without being doped with any modifier material. Alternatively, the electrode structure further comprises a layer of protective film made of a conductive material, and the layer of protective film at least covers the upper surface of the electrode.

Embodiments of the present invention further provide a display substrate, comprising the above electrode structure provided according to embodiments of the present invention.

Embodiments of the present invention further provide a display device, comprising the above display substrate according to embodiments of the present invention.

With the technical solutions of present invention, the carbon nanotube material is doped with the modifier material such that the formed first electrode has a lower square resistance value, thereby meeting the requirement of conductivity of the flexible electrode of the flexible display.

### BRIEF DESCRIPTION OF THE DRAWINGS

FIGS. 1-3 are respectively flow charts of methods of manufacturing an electrode structure according to first to third examples of the present invention.

### DETAILED DESCRIPTION OF PREFERRED EMBODIMENTS OF THE INVENTION

An electrode structure, a method of manufacturing the electrode structure, a display substrate and a display device according to embodiments of the present disclosure will be described hereinafter in detail with reference to the attached drawings.

The methods of manufacturing the electrode structure according to the embodiments of the present disclosure will be described hereinafter in detail in three specific examples.

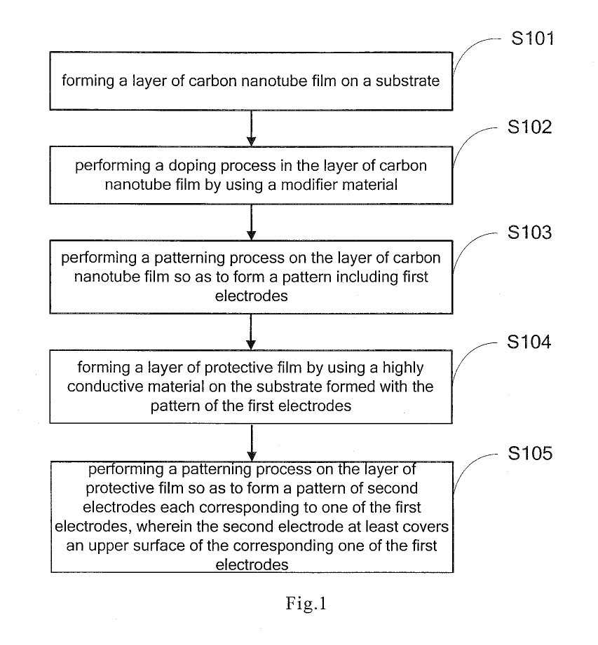

In a first example, a method of manufacturing an electrode structure according to an embodiment of the present invention, as shown in FIG. 1, specifically comprises following steps:

S101: forming a layer of carbon nanotube film on a substrate;

S102: performing a doping process in the layer of carbon nanotube film by using a modifier material; and

S103: performing a patterning process on the doped layer of carbon nanotube film so as to form a pattern including first electrodes.

According to above mentioned method provided by the first example of the present invention, the layer of carbon nanotube film is doped with the modifier material, so that the first electrode formed after the patterning process has a lower square resistance value. Therefore, the first electrode manufactured by using the method according to the first example of the present invention may meet the conductivity requirement of the flexible electrode of the flexible display.

The material of the first electrode is the carbon nanotube material doped with the modifier material, and the stability of the first electrode is poor, thus in an implementation, the method may further comprise, after the step S103 in the first example of the present invention is performed to form the pattern including the first electrodes, following steps, as shown in FIG. 1:

S104: forming a layer of protective film by using a highly conductive material on the substrate formed with the pattern of the first electrodes; and

S105: performing a patterning process on the layer of protective film so as to form a pattern of second electrodes each corresponding to one of the first electrodes, wherein the second electrode at least covers an upper surface of the corresponding one of the first electrodes; that is, the second electrode may only cover the upper surface of the first electrode, or the second electrode may cover the upper surface and a side surface of the corresponding first electrode, which is not particularly limited here. As such, the second electrode may protect the first electrode, making the first electrode have a good stability.

In an implementation, the step S104 in the first example of the present invention, i.e. forming the layer of protective film by using the highly conductive material on the substrate formed with the pattern of the first electrodes, may be achieved by:

coating and drying, on the substrate formed with the pattern of the first electrodes, by using one or more of 3,4-ethylene dioxythiophene/polystyrene sulfonate material (PEDOT/PSS), polyparaphenylene vinyl (PPV), polythiophene based materials, polysilane based materials, triphenylmethane materials, triarylamine-based materials and pyrazoline-based materials. In particular, the highly conductive material for forming the layer of protective film is not limited to the above mentioned materials, and will not be limited here. Specifically, an air knife may be used to dry the abovementioned materials. Of course, other similar methods may also be used to dry the above mentioned materials, and are not particularly limited here.

In an implementation, in the first example of the present invention, the step S101 of forming the layer of carbon nanotube film on the substrate may specifically comprise:

firstly, coating carbon nanotube dispersion liquid on the substrate; and

then performing a drying process on the coated carbon nanotube dispersion liquid. Specifically, the coated carbon nanotube dispersion liquid may be dried through a cleaning machine drying process, or may be dried through other similar processes, which are not particularly limited here. In an implementation, in the first example of the present invention, the step S101 of forming the layer of carbon nanotube film on the substrate may specifically comprise:

firstly, coating a solidifiable material on the substrate; in one example, the solidifiable material may be a thermally solidifiable material or ultraviolet light solidifiable material, which is not particularly limited here;

then forming the layer of carbon nanotube film on the solidifiable material through a film-drawing process; in one example, the film-drawing process may comprise: cutting a carbon nanotube grown on a wafer, placing the carbon nanotube on the substrate coated with the solidifiable material, and drawing the carbon nanotube within a plane parallel to the substrate so as to form the layer of carbon nanotube film; and

finally, performing a solidification treatment on the substrate formed with the layer of carbon nanotube film. Specifically, the solidification treatment may be performed depending on the type of the coated solidifiable material: when the coated solidifiable material is a thermally solidifiable material, the substrate formed with the layer of carbon nanotube film is thermally processed; when the coated solidifiable material is a ultraviolet light solidifiable material, the substrate formed with the layer of carbon nanotube film is irradiated by ultraviolet light.

In an implementation, in the first example of the present invention, the step S102 of performing the doping process in the layer of carbon nanotube film by using the modifier material may comprise:

firstly, placing the substrate formed with the layer of carbon nanotube film into a modifier solution for a preset time;

then, removing the substrate from the modifier solution, and cleaning the substrate by using deionized water; and

finally, drying the cleaned substrate. Specifically, an air knife may be used to dry the cleaned substrate. Of course, other similar methods may also be used to dry the cleaned substrate, and are not particularly limited here.

In an implementation, in the first example of the present invention, placing the substrate formed with the layer of carbon nanotube film into the modifier solution for the preset time may be achieved in following manner: placing the substrate formed with the layer of carbon nanotube film into one or more solutions of nitrogen dioxide (NO₂) solution, bromine (Br₂) solution, nitric acid (HNO₃) solution, thionyl chloride (SOCl₂) solution, perfluorinated sulfonic acid ester (Nafion) solution and tetrafluorotetracyanoquinodimethane subimed (TCNQF₄) solution, preferably, for 5 min to 30 min.

In an implementation, in the first example of the present invention, the step S102 of performing the doping process in the layer of carbon nanotube film by using the modifier material may comprise:

firstly, spraying the modifier solution on the substrate formed with the layer of carbon nanotube film within a preset time;

then, cleaning the substrate sprayed with modifier solution by using deionized water; and

finally drying the cleaned substrate. Specifically, an air knife may be used to dry the cleaned substrate. Of course, other similar methods may also be used to dry the cleaned substrate, and are not particularly limited here.

In an implementation, in the first example of the present invention, spraying the modifier solution on the substrate formed with pattern of the carbon nanotube electrodes within a preset time may be achieved in following manner within a preset time of 5 min to 30 min, spraying one or more of nitrogen dioxide (NO₂) solution, bromine (Br₂) solution, nitric acid (HNO₃) solution, thionyl chloride (SOCl₂) solution, perfluorinated sulfonic acid ester (Nafion) solution and tetrafluorotetracyanoquinodimethane sublimed (TCNQF₄) solution, on the substrate formed with the layer of carbon nanotube film

In an implementation, in the first example of the present invention, the step S103 of performing the patterning process on the doped layer of carbon nanotube film may comprises performing a laser burning process on the doped layer of carbon nanotube film. Of course, the patterning process is not limited to the laser burning process here, and may be other processes such as a photolithography process, which is not particularly limited here.

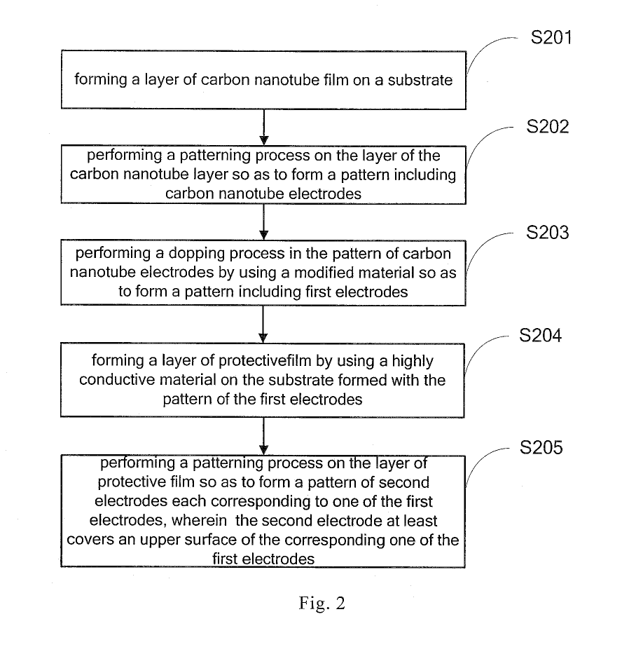

In a second Example, as shown in FIG. 2, a method of manufacturing an electrode structure according to an embodiment of the present invention, specifically, may comprise following steps:

S201: forming a layer of carbon nanotube film on a substrate;

S202: performing a patterning process on the layer of carbon nanotube film so as to form a pattern including carbon nanotube electrodes;

S203: performing a doping process in the pattern of carbon nanotube electrodes by using a modifier material so as to form a pattern including first electrodes.

According to above mentioned method provided by the second example of the present invention, the modifier material is doped in the patterns of carbon nanotube electrodes, so that that the formed first electrode has a lower square resistance value. Therefore, the first electrode manufactured by using the method according to the second example of the present invention may meet the conductivity requirement of the flexible electrode of the flexible display.

The material of the first electrode is the carbon nanotube material doped with the modifier material, and the stability of the first electrode is poor, thus in an implementation, the method may further comprise, after the step S203 in the first example of the present invention is performed to form the pattern including the first electrodes, following steps, as shown in FIG. 2:

S204: forming a layer of protective film by using a highly conductive material on the substrate formed with the pattern of the first electrodes; and

S105: performing a patterning process on the layer of protective film so as to form a pattern of second electrodes each corresponding to one of the first electrodes, wherein the second electrode at least covers an upper surface of the corresponding one of the first electrodes; that is, the second electrode may only cover the upper surface of the first electrode, or the second electrode may cover the upper surface and a side surface of the corresponding first electrode, which is not particularly limited here. As such, the second electrode may protect the first electrode, making the first electrode have a good stability.

In an implementation, the step S201 of forming the layer of carbon nanotube film on the substrate in the second example of the present invention is similar to the step S101 of forming the layer of carbon nanotube film on the substrate in the first example of the present invention, thus the detailed description thereof is omitted here.

In an implementation, the step S202 of performing the patterning process on the layer of carbon nanotube film in the second example of the present invention is similar to the step S103 of performing the patterning process on the doped layer of carbon nanotube film in the first example of the present invention, thus the detailed description thereof is omitted here.

In an implementation, the step S203 of performing the doping process in the pattern of carbon nanotube electrodes by using the modifier material in the second example of the present invention is similar to the step S102 of performing the doping process in the layer of carbon nanotube film by using the modifier material in the first example of the present invention, thus the detailed description thereof is omitted here.

In an implementation, the step S204 of forming the layer of protective film by using the highly conductive material on the substrate formed with the pattern of the first electrodes in the second example of the present invention is similar to the step S104 of forming the layer of protective film by using the highly conductive material on the substrate focused with the pattern of the first electrodes in the first example of the present invention, thus the detailed description thereof is omitted here.

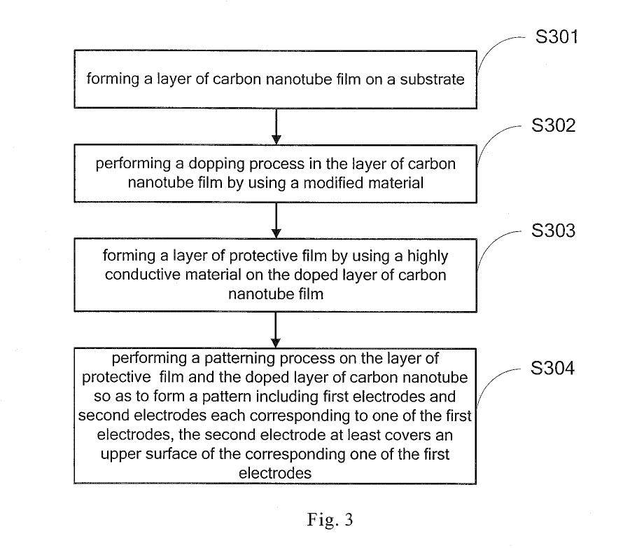

In a third Example, as shown in FIG. 3, a method of manufacturing an electrode structure according to an embodiment of the present invention, specifically, may comprises following steps:

S301: forming a layer of carbon nanotube film on a substrate;

S302: performing a doping process in the layer of carbon nanotube film by using a modifier material;

S303: forming a layer of protective film by using a highly conductive material on the doped layer of carbon nanotube film;

S304: performing a patterning process on the layer of protective film and the doped layer of carbon nanotube film so as to form a pattern including first electrodes and second electrodes; wherein each second electrode corresponds to one of the first electrodes, and at least covers an upper surface of the corresponding one of the first electrodes; that is, the second electrode may only cover the upper surface of the first electrode, or the second electrode may cover the upper surface and a side surface of the corresponding first electrode, which is not particularly limited here. As such, the second electrode may protect the first electrode, making the first electrode have a good stability.

According to above mentioned method according to the third example of the present invention, the modifier material is doped in the layer of carbon nanotube film, so that that the formed first electrode has a lower square resistance value; further, the second electrode on the first electrode may protect the first electrode so as to make the first electrode have a good stability. Therefore, the electrode manufactured by using the method according to the third example of the present invention may not only meet the conductivity requirement of the flexible electrode of the flexible display, but also meet the requirement of long-term stability of the flexible electrode of the flexible display.

In an implementation, the step S301 of performing the doping process in the layer of carbon nanotube film by using the modifier material in the third example of the present invention is similar to the step S102 of performing the doping process in the layer of carbon nanotube film by using the modifier material in the first example of the present invention, thus the detailed description thereof is omitted here.

In an implementation, the step 303 of forming the layer of protective film by using the highly conductive material on the doped layer of carbon nanotube film in the third example of the present invention is similar to the step S104 of forming the layer of protective film by using the highly conductive material on the substrate formed with the pattern of the first electrodes in the first example of the present invention, thus the detailed description thereof is omitted here.

In an implementation, the step S304 of performing the patterning process on the layer of protective film and the doped layer of carbon nanotube film in the third example of the present invention is similar to the step S103 of performing the patterning process on the doped layer of carbon nanotube film in the first example of the present invention, thus the detailed description thereof is omitted here.

Through laboratory tests, the conductivity of the electrode structure made by using the above-described method according to embodiments of the present invention may reach 12, 000 s/cm to 9, 0000 s/cm, the square resistance value thereof may reach 10Ω/□, meeting requirements of flexibility and conductivity of the electrode of flexible display.

It should be noted that the pattern including the first electrodes made by using the above-described method according to embodiments of the present invention may be a unitary structure, for example, may be a pattern of a common electrode formed into an integral in a liquid crystal display panel, or may be a plurality of independent structures, such as a pattern of a plurality of pixel electrodes in the liquid crystal display panel which can display independently; the pattern including the first electrode is not particularly limited here.

Based on the same inventive concept as above, embodiments of the present invention also provide a display substrate, including the above-described electrode structure provided according to the above embodiments of the present invention, the implementation of the display substrate may refer to embodiments of the above-described electrode structure, and will not be repeatedly described.

Exemplarily, the above-described display substrate provided according to embodiments of the present invention may be applied to an advanced super-dimension switch (ADS) type liquid crystal display panel or an In-Plane Switch (IPS) type liquid crystal display panel. The above-described display substrate provided according to embodiments of the present invention may be an array substrate in the ADS type or IPS-type liquid crystal display panel, and the above-described electrode structure provided according to embodiments of the present invention may be a pixel electrode or a common electrode located on one side of the array substrate. The above-described display substrate according to embodiments of the present invention may also be applied to a twisted nematic (TN) type liquid crystal display panel; the above-described display substrate according to embodiments of the present invention may be an array substrate in a TN type liquid crystal panel, and the electrode structure according to embodiments of the present invention may be a pixel electrode located on one side of the array substrate; or, the above-described display substrate according to embodiments of the present invention may also be a color film substrate in the TN type liquid crystal display panel, and the above-described electrode structure according to embodiments of the present invention may be a common electrode located on one side of the color filter substrate; the present invention is not limited to those.

Exemplarily, the display substrate according to embodiments of the present invention can also be applied to an organic electroluminescent display panel (OLED), and the electrode structure according to embodiment of the present invention may be an anode or cathode located on one side of the array substrate in the OLED; the present invention is not limited to this.

Of course, the above-described display substrate according to embodiments of the present invention may also be applied to a display apparatus such as an electronic paper or the like, which is not particularly limited here.

It should be noted that other components of the display substrate according to embodiments of the present invention are substantially the same as the existing structures, and are not particularly limited here.

Based on the same inventive concept as above, an embodiment of the present invention also provides a display device comprising the above-described display substrate according to embodiments of the present invention; the display device may be any product or part which has a display function, such as a mobile phone, a tablet computer, a television, a monitor, a laptop, a digital photo frames or a navigator. Implementation of the display device may refer to those of the above-described display substrate and will not be repeatedly described.

The present invention discloses an electrode structure, a method of manufacturing an electrode structure, a display substrate and a display device. The method of manufacturing an electrode structure includes: forming a layer of carbon nanotube film on a substrate; performing a doping process in the layer of carbon nanotube film by using a modifier material, and performing a patterning process on the doped layer of carbon nanotube film so as to form a pattern including first electrodes; or performing a patterning process on the layer of carbon nanotube film so as to form a pattern including carbon nanotube electrodes, performing a doping process in the pattern of the carbon nanotube electrodes by using a modifier material so as to forming a patterns including first electrodes; as such, the modifier material is doped in the carbon nanotube material, so that the formed first electrode has a relative lower square resistance value, which may meet the conductivity requirement of the flexible electrode of the flexible display.

Although several exemplary embodiments have been shown and described, it would be appreciated by those skilled in the art that various changes or modifications may be made in these embodiments without departing from the principle and spirit of the present invention, the scopes of which are defined in the claims and their equivalents.

1. A method of manufacturing an electrode structure, characterized in that, the method comprising:
forming a layer of carbon nanotube film on a substrate;
performing a doping process in the layer of carbon nanotube film by using a modifier material,
performing a patterning process on the layer of carbon nanotube film so as to form a pattern including first electrodes.

2. The method according to claim 1, wherein after forming the pattern including the first electrodes, the method further comprises:
forming a layer of protective film by using a highly conductive material on the substrate formed with the pattern of the first electrodes,
performing a patterning process on the layer of protective film so as to form a pattern of second electrodes each corresponding to one of the first electrodes, wherein the second electrode at least covers an upper surface of the corresponding one of the first electrodes.

3. The method according to claim 2, wherein forming the layer of protective film by using the highly conductive material on the substrate formed the pattern of the first electrodes comprises:
coating and drying, on the substrate formed with the pattern of the first electrodes, one or more of 3,4-ethylene dioxythiophene/polystyrene sulfonate material, polyparaphenylene vinyl material, polythiophene based materials, polysilane based materials, triphenylmethane based materials, triarylamine-based materials and pyrazoline-based materials.

4. The method according to claim 1, wherein
the patterning process on the layer of carbon nanotube film is performed after performing the doping process in the layer of carbon nanotube film by using the modifier material.

5. The method according to claim 4, wherein
after performing the doping process in the layer of carbon nanotube film, and before performing the patterning process on the doped layer of carbon nanotube film, the method further comprises:
forming a layer of protective film on the doped layer of carbon nanotube film by using a highly conductive material; and
performing the doping process in the doped layer of carbon nanotube film comprises:
performing a patterning process on the layer of protective film and the doped layer of carbon nanotube film so as to form a pattern including the first electrodes and second electrodes, wherein each second electrode corresponds to one of the first electrodes, and the second electrode at least covers an upper surface of the corresponding one of the first electrodes.

6. The method according to claim 5, wherein
forming the layer of protective film on the doped layer of carbon nanotube film by using the highly conductive material comprises:
coating and drying, on the doped layer of carbon nanotube film, one or more of 3,4-ethylene dioxythiophene/polystyrene sulfonate material, polyparaphenylene vinyl material, polythiophene based materials, polysilane based materials, triphenylmethane based materials, triarylamine-based materials and pyrazoline-based materials.

7. The method according to claim 1, wherein
the patterning process on the layer of carbon nanotube film is performed before performing the doping process in the layer of carbon nanotube film by using the modifier material.

8. The method according to claim 1, wherein
forming the layer of carbon nanotube film on the substrate comprises:
coating carbon nanotube dispersion liquid on the substrate; and
performing a drying process on the coated carbon nanotube dispersion liquid.

9. The method according to claim 1, wherein forming the layer of carbon nanotube film on the substrate comprises:
coating a solidifiable material on the substrate;
forming the layer of carbon nanotube film on the solidifiable material through a film-drawing process; and
performing a solidification treatment on the substrate formed with the layer of carbon nanotube film.

10. The method according to claim 1, wherein performing the doping process in the layer of carbon nanotube film comprises:
placing the substrate formed with the layer of carbon nanotube film into a modifier solution for a preset time;
removing the substrate from the modifier solution, and cleaning the substrate by using deionized water, and
drying the cleaned substrate.

11. (canceled)

12. The method according to claim 10, wherein
the modifier solution comprises one or more of nitrogen dioxide solution, bromine solution, nitric acid solution, thionyl chloride solution, perfluorinated sulfonic acid ester solution and tetrafluorotetracyanoquinodimethane subimed solution, the preset time is 5 min to 30 min.

13. The method according to claim 4, wherein performing the doping process in the layer of carbon nanotube film comprises:
spraying modifier solution on the substrate formed with the layer of carbon nanotube film within a preset time;
cleaning the substrate sprayed with modifier solution by using deionized water; and
drying the cleaned substrate.

14. (canceled)

15. The method according to claim 13, wherein the modifier solution comprises one or more of nitrogen dioxide solution, bromine solution, nitric acid solution, thionyl chloride solution, perfluorinated sulfonic acid ester solution and tetrafluorotetracyanoquinodimethane subimed solution, the preset time is 5 min to 30 min.

16. The method according to claim 4, wherein performing the patterning process on the doped layer of carbon nanotube film comprises:
performing a laser burning process on the doped layer of carbon nanotube film.

17. An electrode structure manufactured by using the method according to claim 1.

18. An electrode structure, comprising an electrode made of a carbon nanotube film doped with a modifier material, the carbon nanotube film doped with the modifier material having a lower square resistance value than that of a carbon nanotube film without being doped with any modifier material.

19. The electrode structure according to claim 18, wherein the electrode structure further comprises a layer of protective film made of a conductive material, and the layer of protective film at least covers the upper surface of the electrode.

20. A display substrate comprising the electrode structure according to claim 17.

21. A display device, comprising the display substrate according to claim 20.

21. The method according to claim 7, where performing a patterning process on the layer of carbon nanotube film comprising:
performing a laser burning process on the layer of carbon nanotube film.
